(19) United States
(12) Patent Application Publication
(10) Pub. No.: US 2024/0094639 A1
(43) Pub. Date: Mar. 21, 2024

(54) HIGH-RESOLUTION EVALUATION OF OPTICAL METROLOGY TARGETS FOR PROCESS CONTROL

(71) Applicant: KLA Corporation, Milpitas, CA (US)

(72) Inventors: Nadav Gutman, Zichron Ya'aqov (IL); Dana Klein, Haifa (IL); Slawomir Czerkas, Milpitas, CA (US); Yossi Simon, Milpitas, CA (US); Frank Laske, Weilburg (DE); Mirko Wittkoetter, Milpitas, CA (US)

(21) Appl. No.: 17/948,151

(22) Filed: Sep. 19, 2022

(51) Int. Cl. G03F 7/20; H01L 21/66

(52) U.S. Cl. CPC G03F 7/70625; G03F 7/70633; H01L 22/12

(57) ABSTRACT

A metrology system may include an optical metrology sub-system to generate optical metrology measurements of optical metrology based on features of the optical metrology targets associated with at least one optical pitch and an additional metrology sub-system to generate additional metrology measurements of the optical metrology targets, where the additional metrology measurements have a higher resolution than the optical metrology measurements, and where the additional metrology sub-system further measures deviations of the optical metrology targets from a reference design. The system may further include a controller to generate accuracy measurements for the optical metrology targets based on the measurements, identify variations of a lithography process based on the deviations, correlate the accuracy measurements to the variations, and adjust at least one of the optical metrology sub-system, a lithography tool, or the reference design based on the correlations.

### TECHNICAL FIELD

The present disclosure relates generally to optical metrology and, more particularly, to process control based on high-resolution evaluation of optical metrology targets.

### BACKGROUND

Optical metrology may refer to metrology based on the use of light that typically includes wavelengths in the ultraviolet (UV) to infrared (IR) wavelengths. Many optical metrology techniques rely on measurements of dedicated metrology targets having features designed to facilitate a measurement. However, a measurement accuracy based on such targets may vary in response to deviations of a fabrication process. There is therefore a need to develop systems and methods to evaluate optical metrology targets.

### SUMMARY

A metrology system is disclosed in accordance with one or more illustrative embodiments of the present disclosure. In one illustrative embodiment, the system includes a controller coupled to an optical metrology sub-system and an additional metrology sub-system. In another illustrative embodiment, the optical metrology sub-system is configurable in accordance with a first metrology recipe to generate optical metrology measurements of one or more optical metrology targets on one or more samples, where the optical metrology measurements are based on features of the optical metrology targets associated with at least one optical pitch. In another illustrative embodiment, the additional metrology sub-system is configurable in accordance with a second metrology recipe to generate additional metrology measurements of the one or more optical metrology targets, where the additional metrology measurements have a higher resolution than the optical metrology measurements. In another illustrative embodiment, the additional metrology sub-system further measures deviations of the one or more optical metrology targets from a reference design, where the deviations include deviations of the features associated with the at least one optical pitch relative to the reference design. In another illustrative embodiment, the controller compares the optical metrology measurements with the additional metrology measurements to generate accuracy measurements for the one or more optical metrology targets. In another illustrative embodiment, the controller identifies variations of a lithography process for fabricating the one or more samples based on the deviations of the of the one or more optical metrology targets from the reference design. In another illustrative embodiment, the controller correlates the accuracy measurements of the one or more optical metrology targets to the variations of the lithography process based on the deviations of the of the one or more optical metrology targets from the reference design. In another illustrative embodiment, the controller adjusts at least one of the optical metrology sub-system, a lithography tool, or the reference design based on the correlations.

A method is disclosed in accordance with one or more illustrative embodiments of the present disclosure. In one illustrative embodiment, the method includes generating optical metrology measurements of one or more optical metrology targets on one or more samples with an optical metrology sub-system in accordance with a first metrology recipe, where the one or more optical metrology targets include features associated with at least one optical pitch, and where the optical metrology measurements are based on the features of the optical metrology targets with at least one optical pitch. In another illustrative embodiment, the method includes generating additional metrology measurements of the one or more optical metrology targets with an additional metrology sub-system configurable in accordance with a second metrology recipe, where the additional metrology measurements have a higher resolution than the optical metrology measurements. In another illustrative embodiment, the method includes comparing the optical metrology measurements with the additional metrology measurements to generate accuracy measurements for the one or more optical metrology targets. In another illustrative embodiment, the method includes measuring deviations of the one or more optical metrology targets from a reference design with the additional metrology sub-system, wherein the deviations include deviations of the optically-resolvable features from the reference design. In another illustrative embodiment, the method includes identifying variations of a lithography process for fabricating the one or more samples based on the deviations of the of the one or more optical metrology targets from the reference design. In another illustrative embodiment, the method includes correlating the accuracy measurements of the one or more optical metrology targets to the variations of the lithography process based on the deviations of the of the one or more optical metrology targets from the reference design. In another illustrative embodiment, the method includes adjusting at least one of the optical metrology sub-system, a lithography tool, or the reference design based on the correlations.

A metrology system is disclosed in accordance with one or more illustrative embodiments of the present disclosure. In one illustrative embodiment, the system includes an optical metrology sub-system configurable in accordance with a first metrology recipe to generate optical metrology measurements of one or more optical metrology targets on one or more samples, where the optical metrology measurements are based on features of the optical metrology targets associated with at least one optical pitch. In another illustrative embodiment, the system includes an additional metrology sub-system configurable in accordance with a second metrology recipe to generate additional metrology measurements of the one or more optical metrology targets, where the additional metrology measurements have a higher resolution than the optical metrology measurements. In another illustrative embodiment, the additional metrology sub-system further measures deviations of the one or more optical metrology targets from a reference design, where the deviations include deviations of the features associated with the at least one optical pitch relative to the reference design. In another illustrative embodiment, the system includes a controller. In another illustrative embodiment, the controller compares the optical metrology measurements with the additional metrology measurements to generate accuracy measurements for the one or more optical metrology targets. In another illustrative embodiment, the controller identifies variations of a lithography process for fabricating the one or more samples based on the deviations of the of the one or more optical metrology targets from the reference design. In another illustrative embodiment, the controller correlates the accuracy measurements of the one or more optical metrology targets to the variations of the lithography process based on the deviations of the of the one or more optical metrology targets from the reference design. In another illustrative embodiment, the controller adjusts at least one of the optical metrology sub-system, a lithography tool, or the reference design based on the correlations.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A is a block diagram view of a metrology system, in accordance with one or more embodiments of the present disclosure.

FIG. 1B is a conceptual diagram of the optical metrology sub-system, in accordance with one or more embodiments of the present disclosure.

FIG. 1C is a conceptual diagram of the additional metrology sub-system, in accordance with one or more embodiments of the present disclosure.

FIG. 2 is a conceptual diagram depicting error drivers for process monitoring using optical metrology targets, in accordance with one or more embodiments of the present disclosure.

FIG. 3 is a flow diagram illustrating steps performed in a method, in accordance with one or more embodiments of the present disclosure.

FIG. 4A is a simplified top view of a first design of an optical metrology target, in accordance with one or more embodiments of the present disclosure.

FIG. 4B is a simplified side view of the first design of an optical metrology target depicted in FIG. 4A, in accordance with one or more embodiments of the present disclosure.

FIG. 5A is a simplified top view of a first design of an optical metrology target, in accordance with one or more embodiments of the present disclosure.

FIG. 5B is a simplified side view of the first design of an optical metrology target depicted in FIG. 5A, in accordance with one or more embodiments of the present disclosure.

FIG. 6A is a simplified top view of a first design of an optical metrology target, in accordance with one or more embodiments of the present disclosure.

FIG. 6B is a simplified side view of the first design of an optical metrology target 104 depicted in FIG., in accordance with one or more embodiments of the present disclosure.

FIG. 7 is a conceptual diagram illustrating excursion monitoring based on deviations of an optical metrology target from a reference design, in accordance with one or more embodiments of the present disclosure.

FIG. 8 includes a conceptual diagram depicting the performance of a relatively low-quality reference design of an optical metrology target and a conceptual diagram depicting the performance of a relatively low-quality reference design of an optical metrology target, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods for high-resolution evaluation of metrology targets suitable for optical metrology, referred to herein as optical metrology targets.

Metrology systems in many applications including, but not limited to, semiconductor fabrication commonly generate measurements of metrology targets on a sample, where the metrology targets are designed to facilitate robust and accurate measurements. As an illustration, semiconductor fabrication typically involves the sequential deposition and patterning of layers on a sample to form a device. Metrology in this context may typically be used to monitor various steps of the semiconductor fabrication process to ensure that the steps are performed within fabrication tolerances and/or to provide feedback for control of fabrication tools. These metrology measurements should typically characterize features that will ultimately form the device, which are referred to herein as device features. While it may be possible in some applications to perform metrology measurements directly on the device features, it is often desirable to perform metrology measurements on separate metrology targets distributed throughout the sample. Metrology of device features must typically be highly tailored to the particular layout and in many cases is slow and/or destructive. In contrast, metrology targets may be designed to provide high-throughput and/or non-destructive measurements that are representative of the device features. For example, metrology targets suitable for overlay measurements (e.g., measurements of the registration or misregistration of different lithographic exposures on one or more layers) may include target features associated with different lithographic exposures that are arranged to facilitate robust and accurate overlay measurements.

Various metrology targets and associated metrology techniques have been developed for different situations or applications. For example, some metrology targets are designed for high-resolution measurements with high-resolution metrology tools such as, but not limited to, particle-based metrology tools (e.g., electron-beam metrology tools, ion beam metrology tools, or the like) or X-ray metrology tools. However, such techniques may suffer from relatively low throughput and in some cases may be destructive. As another example, some metrology targets are designed for optical measurements using optical metrology tools based on wavelengths ranging from the ultraviolet (UV) to the infrared (IR) spectral ranges. Optical metrology techniques typically provide relatively high-throughput and non-destructive measurements. However, optical metrology techniques typically require features on an optical metrology target having dimensions and/or pitches on the order of the wavelength of light used for the measurement, which are referred to herein as optical features or coarse features. Such optical features may be substantially larger than the corresponding dimensions and/or pitches of device features.

One challenge of metrology based on optical metrology targets is ensuring that the measurements accurately represent the device features of interest. For example, it may be desirable to provide measurements with an accuracy on a scale of the device features even though the features of the optical metrology target are substantially larger to be compatible with optical measurement techniques. This may require the fabrication of features of the optical metrology target within certain tolerances. Deviations of the optical metrology target from a reference design may thus reduce the accuracy of measurements based on the target and thus reduce the effectiveness of process control based on these measurements.

The accuracy at which features on a photomask (e.g., a reticle) may be imaged onto a sample during a lithographic exposure may depend on a range of factors including, but not limited optical characteristics of a lithography tool (e.g., wavelength, numerical aperture, depth of field, or the like) and characteristics of the pattern (e.g., feature size, feature density, feature orientation, or the like). In this way, optical features on a sample may be printed with different characteristics than device features.

Accordingly, some optical metrology target designs additionally include features (e.g., fine features) having dimensions and/or pitches that correspond to the device features to provide that the characteristics of the printed optical features more accurately correspond to the characteristics of the printed device features. For example, optical features may be segmented to include fine features with similar dimensions and/or pitches as device features.

However, it may still be the case that aberrations and/or temporal variations of a lithographic exposure may impact optical features differently than the fine features. Variations in the lithography process (e.g., drifts, excursions, or the like) may thus impact optical features differently than the fine features.

It is therefore desirable to evaluate the performance of optical metrology targets to ensure that the constituent features are printed according to a reference design and thus to ensure an accurate measurement. The resulting information may be used for process control during fabrication (e.g., as data in feedback and/or feedforward process control loops) and/or to compare the performance of different target designs.

Embodiments of the present disclosure are directed to direct measurement of deformations of optical metrology targets (e.g., deviations of the optical metrology targets from a reference design) using high-resolution metrology techniques such as, but not limited to, particle-based metrology techniques or X-ray metrology techniques. For example, deformations such as, but not limited to, feature asymmetry or pitch-dependent pattern placement error (PPE) may be measured. It is contemplated herein that such deformations may represent significant contributions to errors associated with optical metrology.

Further, direct measurements of such deformations of an optical target may be performed at any stage of a fabrication process including, but not limited to, directly after exposure of a photoresist prior to an etching step (e.g., an after-development inspection (ADI) step) or after an etching step (e.g., an after-etch inspection (AEI) step). It is contemplated herein that direction measurements of the deformation of an optical metrology target as disclosed herein may provide superior performance than alternative techniques for evaluating an optical overlay target.

In embodiments, a metrology system includes an optical metrology sub-system and an additional metrology sub-system having a higher resolution than the optical metrology tool. Such an additional metrology sub-system may include, but is not limited to, a particle-beam metrology sub-system or an X-ray metrology sub-system.

In embodiments, the optical metrology sub-system generates optical overlay measurements of a series of optical overlay targets. For example, the optical overlay targets may include features having at least one optical pitch, where the optical metrology sub-system generates the optical overlay measurements based on light diffracted and/or scattered by the at least one optical pitch (e.g., a pitch resolvable by an optical metrology system). In embodiments, the additional metrology sub-system further generates additional overlay measurements of at least some of the optical metrology targets. For example, the additional metrology sub-system may measure deviations of the optical metrology target including, but not limited to, asymmetry or PPE of features associated with the at least one optical pitch. As another example, the additional metrology sub-system may measure etch bias (e.g., differences between a developed resist prior to etching and an etched pattern).

In embodiments, the metrology system measures deviations of the one or more overlay targets from a reference design based on the additional measurements, wherein the deviations include deviations of the features associated with the at least one optical pitch from the reference design.

In embodiments, the metrology system further identifies variations of a lithography process for fabricating the one or more samples based on the deviations of the of the one or more overlay targets from the reference design. For example, the deviations of the overlay targets may be associated with drifts of the lithography process.

In embodiments, the metrology system further correlates the accuracy measurements of the one or more overlay targets to the variations of the lithography process based on the deviations of the of the one or more overlay targets from the reference design. In this way, the accuracy of the overlay measurements in the presence of variations of the lithography process may be evaluated.

In embodiments, the metrology system further takes one or more actions based on these correlations. For example, in an initial design phase, optical overlay targets having different reference designs may be evaluated and a preferred design may be selected. For instance, a preferred design may provide a relatively high accuracy despite variations of the lithography process. As another example, in a high-volume manufacturing phase, the reference design for the optical overlay targets may be switched and/or a metrology recipe for characterizing an optical overlay target with the optical metrology sub-system may be updated to improve performance in response to variations of the lithography process.

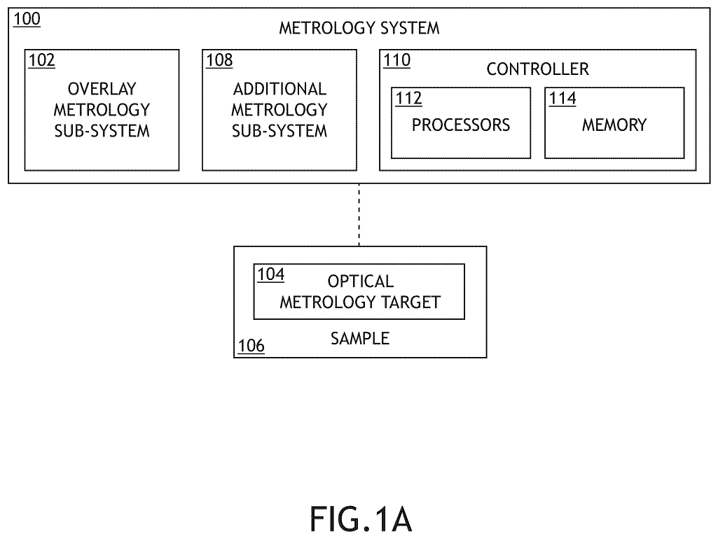

Referring now to FIGS. 1A-8, systems and methods for evaluating optical metrology targets are described in greater detail, in accordance with one or more embodiments of the present disclosure.

FIG. 1A is a block diagram view of a metrology system 100, in accordance with one or more embodiments of the present disclosure.

In embodiments, the metrology system 100 includes an optical metrology sub-system 102 suitable for generating optical metrology measurements of an optical metrology target 104 on a sample 106.

The optical metrology target 104 may include any number or arrangement of target features suitable for characterization by the optical metrology sub-system 102. In embodiments, the optical metrology target 104 includes features associated with at least one optical pitch, where the optical metrology sub-system 102 generates an optical metrology measurement based on the at least one optical pitch. In some embodiments, the optical metrology target 104 further includes features associated with at least one fine pitch smaller than an optical pitch. For example, the fine pitch may be similar to or representative of a pitch of design features that the optical metrology target 104 is designed to characterize. In this way, features with the fine pitch may be printed (e.g., exposed in a lithographic process) with similar characteristics as the device features.

The optical metrology sub-system 102 may include any combination of components suitable for generating an optical metrology measurement of the optical metrology target 104. For example, the optical metrology sub-system 102 may include an imaging sub-system and provide an optical metrology measurement based on one or more images of the optical metrology sub-system 102 in which the at least one optical pitch is resolved. In cases where the optical metrology target 104 further includes features with a fine pitch, the fine pitch may not be resolved in the images. As another example, the optical metrology sub-system 102 may include a scatterometry sub-system and provide an optical metrology measurement based on relative intensities of diffraction orders from the at least one optical pitch (e.g., as measured in a pupil plane). In cases where the optical metrology target 104 further includes features with a fine pitch, diffraction may not be collected or may not be utilized in the measurement.

The optical metrology sub-system 102 may utilize light with any wavelength or combination of wavelengths to generate an optical metrology measurement of the optical metrology target 104. For example, the optical metrology sub-system 102 may utilize light with wavelengths in the UV to IR spectral regions.

In embodiments, the metrology system 100 includes an additional metrology sub-system 108, which may be referred to as a high-resolution metrology sub-system. For example, the additional metrology sub-system 108 may including an imaging system suitable for resolving the positions and/or profiles of the optical metrology target 104. As an illustration, the additional metrology sub-system 108 may be suitable for measuring characteristics of the optical metrology target 104 including, but not limited to, sidewall angles of the constituent features (and thus asymmetries of the features) or PPE of the constituent features. Further, in cases where the optical metrology target 104 includes fine features at a fine pitch, the additional metrology sub-system 108 may provide such characteristics for the fine features.

The additional metrology sub-system 108 may include any combination of components suitable for resolving the positions and/or profiles of the optical metrology target 104. For example, the additional metrology sub-system 108 may include a particle-based metrology sub-system such as, but not limited to, an electron-beam metrology sub-system (e.g., a scanning electron microscope, or the like) or an ion beam metrology sub-system. As another example, the additional metrology sub-system 108 may include an X-ray metrology sub-system.

In embodiments, the additional metrology sub-system 108 has a higher resolution than the optical metrology sub-system 102 and may individually characterize features of the optical metrology target 104 on one or more sample layers. For example, it may be the case that the optical metrology sub-system 102 may generate an optical metrology measurement based on two diffraction orders of the optical metrology target 104. In this case, the optical metrology sub-system 102 need not necessarily resolve aspects of individual features of the optical metrology target 104 such as sidewall angles or the like. In contrast, the additional metrology sub-system 108 may fully resolve such aspects of the individual features.

Some embodiments of the present disclosure are directed to providing recipes for configuring the optical metrology sub-system 102 and/or the additional metrology sub-system 108. A metrology recipe may include a set of parameters for controlling various aspects of a metrology measurement. Further, the optical metrology sub-system 102 and the additional metrology sub-system 108 may utilize different metrology recipes (e.g., first and second recipes, or the like).

For example, a metrology recipe may include parameters such as, but not limited to, the illumination of an optical metrology target 104, the collection of light from the sample, or the position of the sample during a measurement. In this way, the optical metrology sub-system 102 may be configured to provide a selected type of measurement for a selected target design (e.g., reference design).

As an illustration, a metrology recipe for a light-based metrology sub-system (e.g., the optical metrology sub-system 102 or an X-ray based additional metrology sub-system 108) may include parameters of an illumination beam such as, but not limited to, an illumination wavelength, an illumination pupil distribution (e.g., a distribution of illumination angles and associated intensities of illumination at those angles), a polarization of incident illumination, or a spatial distribution of illumination. Similarly, a metrology recipe for a particle-based metrology sub-system (e.g., a particle-based additional metrology sub-system 108) may include illumination parameters such as, but not limited to, an accelerating voltage, a beam current, a spot size of the illumination beam, or a scan speed.

As another illustration, a metrology recipe for a light-based metrology sub-system may include collection parameters such as, but not limited to, a collection pupil distribution (e.g., a desired distribution of angular light from the optical metrology target 104 to be used for a measurement and associated filtered intensities at those angles), collection field stop settings to select portions of the optical metrology target 104 of interest, polarization of collected light, wavelength filters, or parameters for controlling one or more detectors. Similarly, a metrology recipe for a particle-based metrology sub-system may include collection parameters such as, but not limited to, a voltage applied to a collection lens or a detector type.

By way of another example, a metrology recipe may include various parameters associated with a design of the optical metrology target 104 such as, but not limited to, positions and orientations of sample features (e.g., pitches of grating features along particular directions). By way of a further example, a metrology recipe may include various parameters associated with the position of the sample 106 during a measurement such as, but not limited to, a sample height, a sample orientation, whether a sample 106 is static during a measurement, or whether a sample 106 is in motion during a measurement (along with associated parameters describing the speed, scan pattern, or the like).

In embodiments, the metrology system 100 includes a controller 110 communicatively coupled to any components therein. In some embodiments, the controller 110 includes one or more processors 112. For example, the one or more processors 112 may be configured to execute a set of program instructions maintained in a memory 114, or memory device. The one or more processors 112 of a controller 110 may include any processing element known in the art. In this sense, the one or more processors 112 may include any microprocessor-type device configured to execute algorithms and/or instructions.

The one or more processors 112 of a controller 110 may include any processor or processing element known in the art. For the purposes of the present disclosure, the term “processor” or “processing element” may be broadly defined to encompass any device having one or more processing or logic elements (e.g., one or more microprocessor devices, one or more application specific integrated circuit (ASIC) devices, one or more field programmable gate arrays (FPGAs), or one or more digital signal processors (DSPs)). In this sense, the one or more processors 112 may include any device configured to execute algorithms and/or instructions (e.g., program instructions stored in memory). In some embodiments, the one or more processors 112 may be embodied as a desktop computer, mainframe computer system, workstation, image computer, parallel processor, networked computer, or any other computer system configured to execute a program configured to operate or operate in conjunction with the metrology system 100, as described throughout the present disclosure. Moreover, different subsystems of the metrology system 100 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers. Additionally, the controller 110 may include one or more controllers housed in a common housing or within multiple housings. In this way, any controller or combination of controllers may be separately packaged as a module suitable for integration into the metrology system 100.

The memory 114 may include any storage medium known in the art suitable for storing program instructions executable by the associated one or more processors 112. For example, the memory 114 may include a non-transitory memory medium. By way of another example, the memory 114 may include, but is not limited to, a read-only memory (ROM), a random-access memory (RAM), a magnetic or optical memory device (e.g., disk), a magnetic tape, a solid-state drive and the like. It is further noted that the memory 114 may be housed in a common controller housing with the one or more processors 112. In some embodiments, the memory 114 may be located remotely with respect to the physical location of the one or more processors 112 and the controller 110. For instance, the one or more processors 112 of the controller 110 may access a remote memory (e.g., server), accessible through a network (e.g., internet, intranet and the like).

The controller 110 may direct (e.g., through control signals) and/or receive data from any components or sub-systems of the metrology system 100 such as, but not limited to, the optical metrology sub-system 102 or the additional metrology sub-system 108. The controller 110 may further be configured to perform any of the various process steps described throughout the present disclosure.

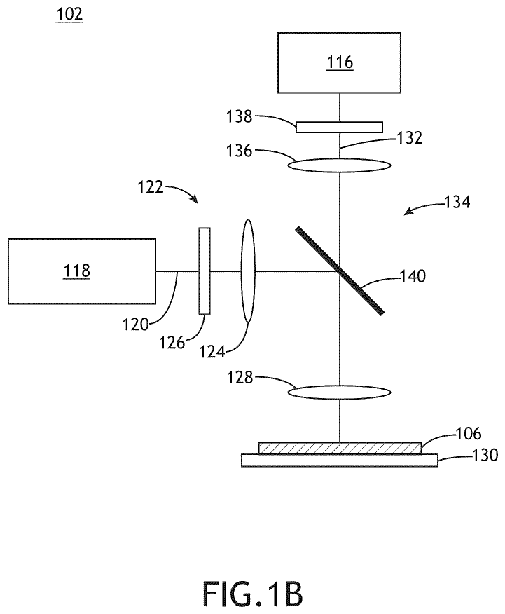

Referring now to FIG. 2, high-resolution evaluation of optical metrology targets 104 to facilitate process control is described in greater detail, in accordance with one or more embodiments of the present disclosure. FIG. 2 is a conceptual diagram depicting error drivers for process monitoring using optical metrology targets, in accordance with one or more embodiments of the present disclosure.

As described previously herein, it may be desirable to evaluate the printing characteristics of optical metrology target 104 to ensure that metrology measurements based on the targets remains accurate (e.g., within an accuracy metric).

One option for evaluating an optical metrology target 104 is to use optical techniques. Optical techniques for evaluation of metrology targets are generally described in D. Kandel, et al., OVERLAY ACCURACY FUNDAMENTALS, Proc. SPIE 8324, Metrology, Inspection, and Process Control for Microlithography XXVI, 832417 (5 Apr. 2012); A. Shchegrov, et al., ON PRODUCT OVERLAY METROLOGY CHALLENGES IN ADVANCED NODES, Proc. SPIE 11325, Metrology, Inspection, and Process Control for Microlithography XXXIV, 113251P (20 Mar. 2020); and E. Amit, et al., OVERLAY ACCURACY CALIBRATION, Proc. SPIE 8681, Metrology, Inspection, and Process Control for Microlithography XXVII, 86811G (18 Apr. 2013), all of which are incorporated herein by reference in their entireties. However, the wavelength of light used for such optical evaluations may limit the achievable resolution.

A second option for evaluating an optical metrology target 104 is to utilize external references such as additional targets, or portions of targets suitable for characterization by a high-resolution metrology tool (e.g., a particle-beam metrology tool, an X-ray metrology tool, or the like). For instance, a high-resolution target may include fine features having dimensions and/or pitches similar to device features and may typically have a small size suitable for measurement with a high-resolution metrology tool. Techniques for evaluating and/or calibrating an optical metrology target 104 based on high-resolution measurements of external references is described generally in U.S. Pat. No. 11,075,126 entitled MISREGISTRATION MEASUREMENTS USING COMBINED OPTICAL AND ELECTRON BEAM TECHNOLOGY and issued on Jul. 27, 2021; N. Gutman, et al., OPTICAL IMAGING METROLOGY CALIBRATION USING HIGH VOLTAGE SCANNING ELECTRON MICROSCOPE AT AFTER-DEVELOPMENT INSPECTION FOR ADVANCED PROCESSES, Proc. SPIE 11325, Metrology, Inspection, and Process Control for Microlithography)(XXIV, 113251X (20 Mar. 2020); and S. Czerkas, et al., HIGH VOLTAGE SCANNING ELECTRON MICROSCOPE OVERLAY METROLOGY ACCURACY FOR AFTER DEVELOPMENT INSPECTION, Proc. SPIE 11611, Metrology, Inspection, and Process Control for Semiconductor Manufacturing XXXV, 116110B (22 Feb. 2021), all of which are incorporated herein by reference in their entireties.

In FIG. 2, bar chart 202 depicts the relative contributions of different target quality errors (e.g., deviations from a reference design, deformations, or the like) related to accuracy instability for an optical metrology target 104 characterized using optical techniques and for a dedicated high-resolution target characterized using a high-resolution metrology sub-system. In particular, bar chart 202 depicts the relative contributions of target asymmetry and PPE. However, FIG. 2 is provided solely for illustrative purposes and should not be interpreted as limiting. Rather, any contributions to target quality errors including, but not limited to, etch bias are within the spirit and scope of the present disclosure.

As depicted in FIG. 2, high-resolution characterization of dedicated high-resolution targets may provide significantly more accurate measurements of deformations such as asymmetry or PPE than corresponding optical measurements of optical metrology targets 104. This is illustrated by the differential 204 depicted in FIG. 2. However, it is contemplated herein that measurements of external features such as dedicated high-resolution targets may fail to capture deformations of optical features of an optical metrology target 104 and may thus fail to adequately evaluate the performance of an optical metrology targets 104.

For example, it may be the case that optical features having dimensions and/or pitches suitable for optical characterization may be more sensitive to process deviations (e.g., variations of a lithography process) than fine features. In fact, lithography processes are often designed to provide that device features (and thus corresponding fine features of an optical metrology target 104) are relatively insensitive to process variations to minimize the impact of such process variations on the device features. As a result, fine features associated with a dedicated high-resolution metrology target may also be insensitive to process variations.

Embodiments of the present disclosure are directed to directly measuring deformations of an optical metrology target 104 (e.g., deviations from a reference design) using high-resolution metrology tools. In this way, deformations of optical features suitable for optical characterization may be captured with the high-resolution metrology tool.

The left panel 206 of FIG. 2 further depicts a portion of an optical metrology target 104 including an optical feature 208 segmented with fine features 210. In embodiments, the optical feature 208 as well as any fine features 210 are evaluated with a high-resolution metrology tool (e.g., the additional metrology sub-system 108). Further, such features may be, but are not required to be, evaluated using more than one region of interest (ROI). For example, a first ROI 212 (e.g., a fine-pitch ROI) may be suitable for capturing PPE and/or asymmetries of the fine features 210, whereas a second ROI 214 (e.g., an optical ROI) may be suitable for capturing PPE and/or asymmetries of the optical feature 208.

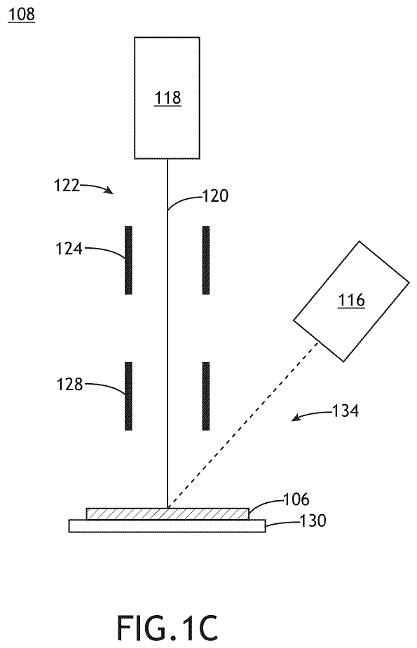

Referring now to FIG. 3, FIG. 3 is a flow diagram illustrating steps performed in a method 300, in accordance with one or more embodiments of the present disclosure. Applicant notes that the embodiments and enabling technologies described previously herein in the context of the metrology system 100 should be interpreted to extend to the method 300. It is further noted, however, that the method 300 is not limited to the architecture of the metrology system 100.

In embodiments, the method 300 includes a step 302 of generating optical metrology measurements of one or more optical metrology targets 104 on one or more samples with an optical metrology sub-system 102 in accordance with a first metrology recipe, where the optical metrology measurements are based on the features of the optical metrology targets 104 with at least one optical pitch.

The optical metrology targets 104 may be based on any type of target design suitable for characterization by the optical metrology sub-system 102. Further, the optical metrology targets 104 may include features having any number of different pitches. For example, an optical metrology target 104 may include features with one or more optical pitches (e.g., an optical pitch 208 as depicted in FIG. 2). As another example, an optical metrology target 104 may include features distributed with a fine pitch (e.g., a fine pitch 210 as depicted in FIG. 2) that may be similar to or representative of a pitch of device features. In some cases, an optical metrology target 104 includes optical features distributed with an optical pitch, where the optical features are segmented into smaller fine features distributed with a fine pitch.

Further, the optical metrology measurement may be determined using any suitable technique. For example, the step 302 may include generating optical metrology measurements using model-based or model-less techniques.

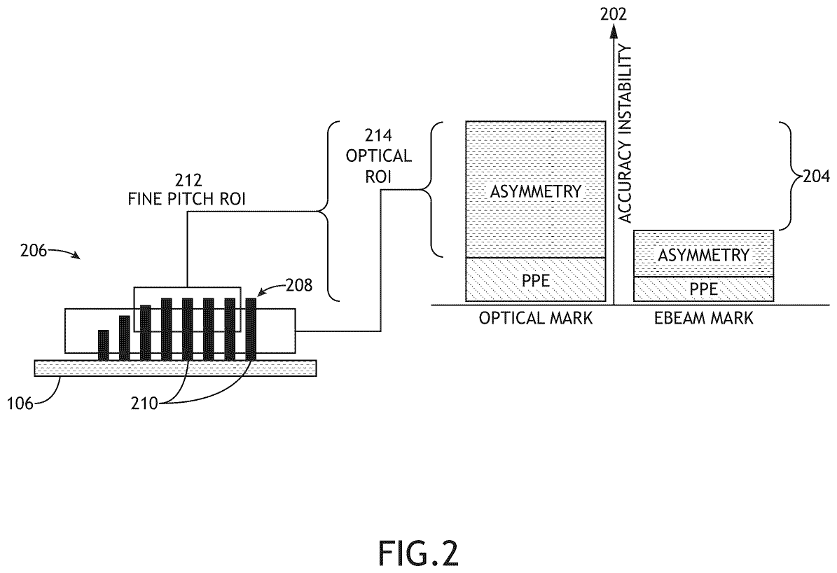

FIGS. 4A-6B depict various non-limiting illustrations of designs (e.g., reference designs) for an optical metrology target 104, in accordance with one or more embodiments of the present disclosure. In particular, FIGS. 4A-6B depict various designs of an optical metrology target 104 suitable for overlay measurements (e.g., overlay targets). In each of FIGS. 4A-6B, an optical metrology target 104 includes first-layer features 402 on a first layer 404 of a sample 106 and second-layer features 406 on a second layer 408 of the sample 106. In this way, FIGS. 4A-6B depict variations of an optical metrology target 104 suitable for overlay measurements between the first layer 404 and the second layer 408. Further, the first layer 404 and the second layer 408 may correspond to any suitable layers. In some embodiments, the first layer 404 is a process layer and includes first-layer features 402 formed through development (e.g., lithographic exposure) and etching steps, whereas the second layer 408 is a resist layer and includes second-layer features 406 formed through a development step. Such a configuration may correspond to an after-development inspection (ADI) step. In some embodiments, both the first layer 404 and the second layer 408 are process layers such that both the first-layer features 402 and the second-layer features 406 are formed through development and etching steps. Such a configuration may correspond to an after-etch inspection (AEI) step.

However, the depiction of optical metrology targets 104 in FIGS. 4A-6B is merely illustrative and should not be interpreted as limiting. For example, an optical metrology target 104 suitable for overlay measurements may include features associated with different exposures in a single layer (e.g., based on multi-patterning techniques) or features associated with different exposures in three or more layers for overlay measurements between any of the three or more layers. As another example, optical metrology targets 104 are not limited to overlay metrology and optical metrology targets 104 associated with any type of optical metrology measurement are within the spirit and scope of the present disclosure. In some embodiments, an optical metrology target 104 is formed as a hybrid target suitable for both optical and particle-beam based metrology techniques. Non-limiting examples of hybrid targets are described generally in U.S. patent application Ser. No. 17/487,725 filed on Sep. 28, 2021, which is incorporated herein by reference in its entirety.

FIG. 4A is a simplified top view of a first design of an optical metrology target 104, in accordance with one or more embodiments of the present disclosure. FIG. 4B is a simplified side view of the first design of an optical metrology target 104 depicted in FIG. 4A, in accordance with one or more embodiments of the present disclosure.

In FIGS. 4A and 4B, first-layer features 402 and second-layer features 406 have a common pitch (e.g., an optical pitch) are arranged in non-overlapping regions of the optical metrology target 104. Such an arrangement may be suitable for, but is not limited to, imaging-based optical metrology. For example, FIGS. 4A and 4B may be representative of one cell of an advanced imaging metrology (AIM) optical metrology target 104.

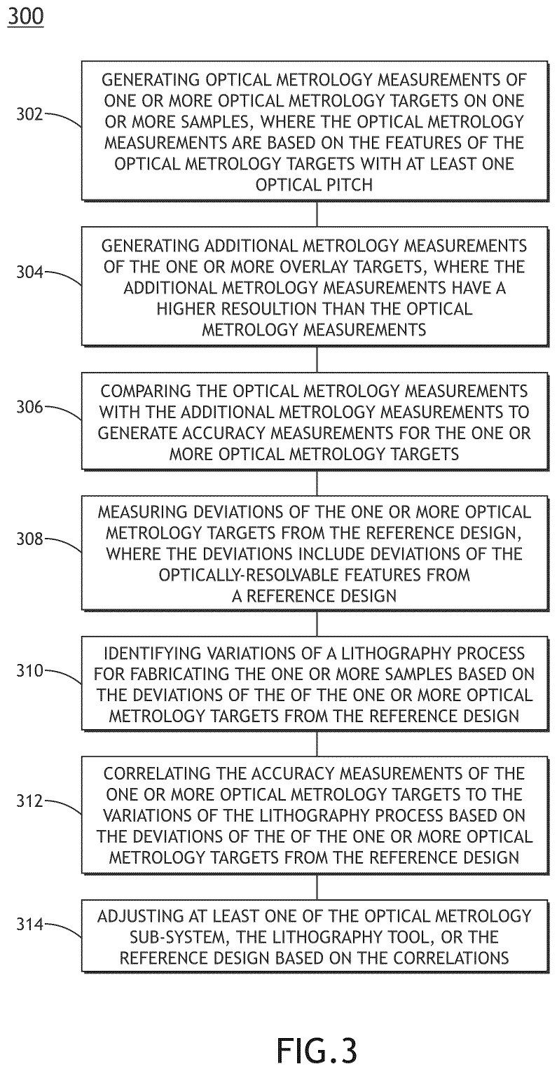

FIG. 5A is a simplified top view of a first design of an optical metrology target 104, in accordance with one or more embodiments of the present disclosure. FIG. 5B is a simplified side view of the first design of an optical metrology target 104 depicted in FIG. 5A, in accordance with one or more embodiments of the present disclosure.

In FIGS. 5A and 5B, first-layer features 402 and second-layer features 406 have a common pitch (e.g., an optical pitch) and are arranged in overlapping regions of the optical metrology target 104. Such an arrangement may be suitable for, but is not limited to, scatterometry-based optical metrology. For example, FIGS. 45 and 5B may be representative of a cell of a scatterometry optical metrology target 104, where different cells may have different intentional offsets between the first-layer features 402 and the second-layer features 406.

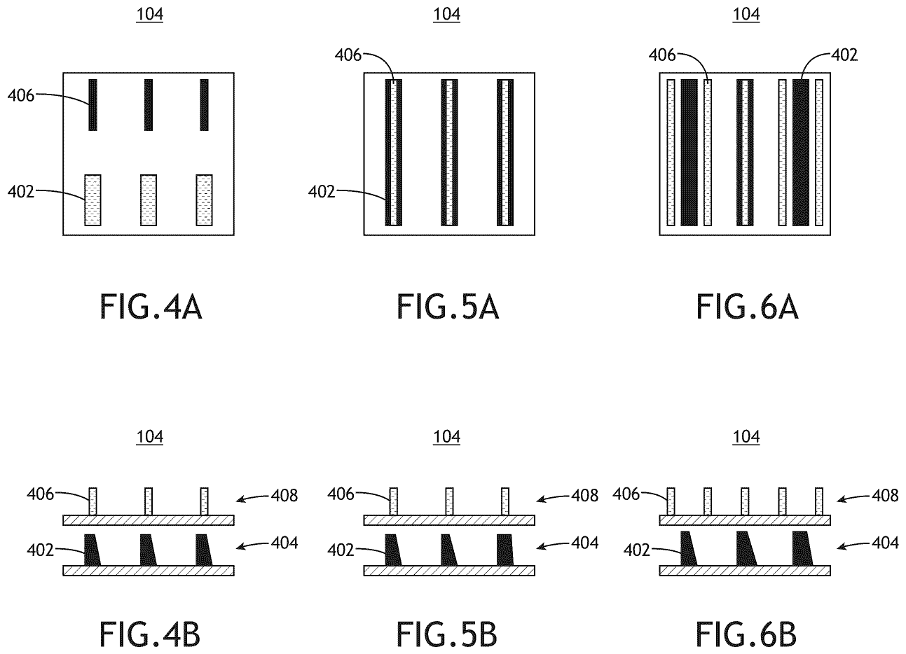

FIG. 6A is a simplified top view of a first design of an optical metrology target 104, in accordance with one or more embodiments of the present disclosure. FIG. 6B is a simplified side view of the first design of an optical metrology target 104 depicted in FIG. 6A, in accordance with one or more embodiments of the present disclosure.

In FIGS. 6A and 6B, first-layer features 402 and second-layer features 406 have different pitches and are arranged in overlapping regions of the optical metrology target 104 to form a Moiré structure. Such a configuration may generate diffraction orders associated with each of the different pitches as well as Moiré diffraction orders associated with double diffraction (e.g., combined diffraction) from each of the structures, where optical overlay metrology measurements may be generated based on any of diffraction orders, alone or in combination, using different techniques. For example, both pitches of the first-layer features 402 and second-layer features 406 may be optical pitches such that optical overlay metrology measurements may be generated based on diffraction from these structures. As another example, the pitches of the first-layer features 402 and/or second-layer features 406 may be below an imaging resolution of the optical metrology sub-system 102, but the Moiré diffraction order may be an optical pitch and used for the generation of an optical overlay metrology measurement.

Further, referring generally to FIGS. 4A-6B, although not shown, any of the first-layer features 402 or the second-layer features 406 may be further segmented to include fine structures distributed with a fine pitch as described previously herein.

In embodiments, the method 300 includes a step 304 of generating additional metrology measurements of the one or more overlay targets with an additional metrology sub-system 108 configurable in accordance with a second metrology recipe, where the additional metrology measurements have a higher resolution than the optical metrology measurements. For example, in the case of an image-based optical metrology sub-system 102, the additional metrology sub-system 108 may have a higher imaging resolution than the optical metrology sub-system 102. As another example, in the case of a scatterometry-based optical metrology sub-system 102, the additional metrology sub-system 108 may have a higher measurement accuracy than the optical metrology sub-system 102.

In embodiments, the method 300 includes a step 306 of comparing the optical metrology measurements with the additional metrology measurements to generate accuracy (or inaccuracy) measurements for the one or more optical metrology targets 104. In this way, various errors associated with the optical metrology measurements may be determined. Such errors may be systematic and occur consistently for all optical metrology targets 104, may be dependent on a location of an optical metrology target 104 on a sample 106 (e.g., a location within an exposure field and/or a location across a sample 106), and/or may be time-varying (e.g., may vary for optical metrology targets 104 in consistent locations across multiple samples 106 in the same or different lots).

In embodiments, the method 300 includes a step 308 of measuring deviations of the one or more optical metrology targets 104 from the reference design with the additional metrology sub-system 108, where the deviations include deviations of the optically-resolvable features from a reference design. In embodiments, the method 300 includes a step 310 of identifying variations of a lithography process for fabricating the one or more samples 106 based on the deviations of the of the one or more optical metrology targets from the reference design. In a manner similar to step 306, variations of the lithography process may be dependent on a location of an optical metrology target 104 on a sample 106, and/or may be time-varying. Such variations in the lithography process may induce the deviations measured in step 308. In this way, deviations of the optical metrology targets 104 from the reference design measured in step 308 may serve as an indicator of variations of the lithography process.

The reference design may include designed (e.g., ideal) dimensions, orientations, and/or placements of all features of the optical metrology target 104. For example, the reference design may include characteristics such as, but not limited to, sidewall angles or designed symmetries or asymmetries of any features (e.g., features associated with an optical pitch and/or features associated with a fine pitch).

Accordingly, the step 308 may include measurements of deviations of any design characteristic of any of the features of the optical metrology target 104 such as, but not limited to, deviations of the placement of any features (e.g., PPE of the features), deviations of one or more sidewall angles, symmetry deviations (e.g., unintended asymmetries, pitch splitting, asymmetric pitch walk, asymmetric contour misplacement (EPE)) of any of the features or combinations of features, or etch bias errors.

The step 308 may include individual measurements of specific features and/or groups of features. For example, the step 308 may include layer-specific deviation measurements. In this case, features on different layers of the sample 106 may exhibit different printing errors, which may be identified in step 308. As an illustration FIGS. 3A-5B depict asymmetric first-layer features 402, but symmetric second-layer features 406. In cases where all features are intended to be symmetric (e.g., in the reference design), such asymmetries of the first-layer features 402 may be identified in step 308.

As another example, the step 308 may include pitch-specific deviation measurements. In this case, features associated with different pitches may exhibit different printing errors, which may be identified in step 308. For example, an optical metrology target 104 including optical features distributed with an optical pitch segmented with fine features distributed with a fine pitch may exhibit different printing errors for the optical and fine features, which may be identified in step 308.

In embodiments, the method 300 includes a step 312 of correlating the accuracy measurements of the one or more optical metrology targets 104 to the variations of the lithography process (e.g., excursions) based on the deviations of the one or more optical metrology targets 104 from the reference design. In this way, impact of variations of the lithography process on the accuracy of the optical overlay measurements may be determined.

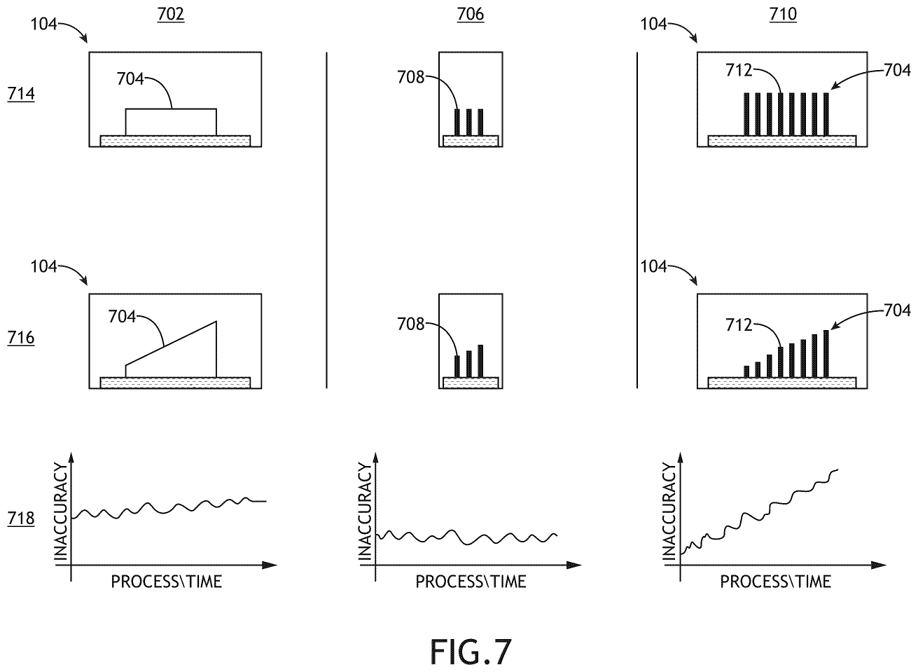

FIG. 7 is a conceptual diagram illustrating excursion monitoring (e.g., monitoring process variations) based on deviations of an optical metrology target 104 from a reference design, in accordance with one or more embodiments of the present disclosure.

Panel 702 depicts excursion monitoring based on evaluation of an optical metrology target 104 using optical techniques. In particular, panel 702 illustrates a single representative optical feature 704 having dimensions and/or a pitch (additional structures not shown) suitable for optical characterization.

Panel 706 depicts excursion monitoring based on evaluation of a high-resolution metrology target using a high-resolution metrology tool. In particular, panel 706 illustrates multiple representative fine features 708 having dimensions and/or a pitch similar to that of corresponding device features.

Panel 710 depicts excursion monitoring of an optical metrology target 104 based on excursion monitoring based on evaluation of an optical metrology target 104 using a high-resolution metrology tool (e.g., the additional metrology sub-system 108) as disclosed herein. In particular, panel 710 illustrates the optical feature 704 as well as constituent fine features 712 that are resolvable with the additional metrology sub-system 108 but not necessarily by the optical metrology sub-system 102.

In each panel, row 714 depicts a side profile of a first representative target as measured by the respective tool. Row 716 depicts a side profile of a second representative target as measured by the respective tool, where the second representative target exhibits an asymmetry error as a result of process deviations.

Row 718 then depicts conceptual plots of a measured inaccuracy of the respective targets as measurable by the respective tool in response to process deviations. Further, such process deviations may occur spatially (e.g., as a function of position on the sample 106) and/or across time (e.g., across multiple sample 106). As depicted in panel 710, excursion monitoring of an optical metrology target 104 based on excursion monitoring based on evaluation of an optical metrology target 104 using a high-resolution metrology tool (e.g., the additional metrology sub-system 108) as disclosed herein provides a highly sensitive evaluation of the asymmetry of the optical feature 704 in addition to characteristics of the fine features 712. As a result, this technique may provide a highly sensitive evaluation of the inaccuracy of an associated optical metrology target 104 in response to process variations.

Referring again to FIG. 3, in embodiments, the method 300 includes a step 314 of adjusting at least one of the optical metrology sub-system, the lithography tool, or the reference design based on the correlations.

It is contemplated herein that the correlation between the accuracy measurements of the one or more optical metrology targets 104 to the variations of the lithography process (e.g., excursions) based on the deviations of the of the one or more optical metrology targets 104 from the reference design as measured in step 312 may be used in a variety of ways.

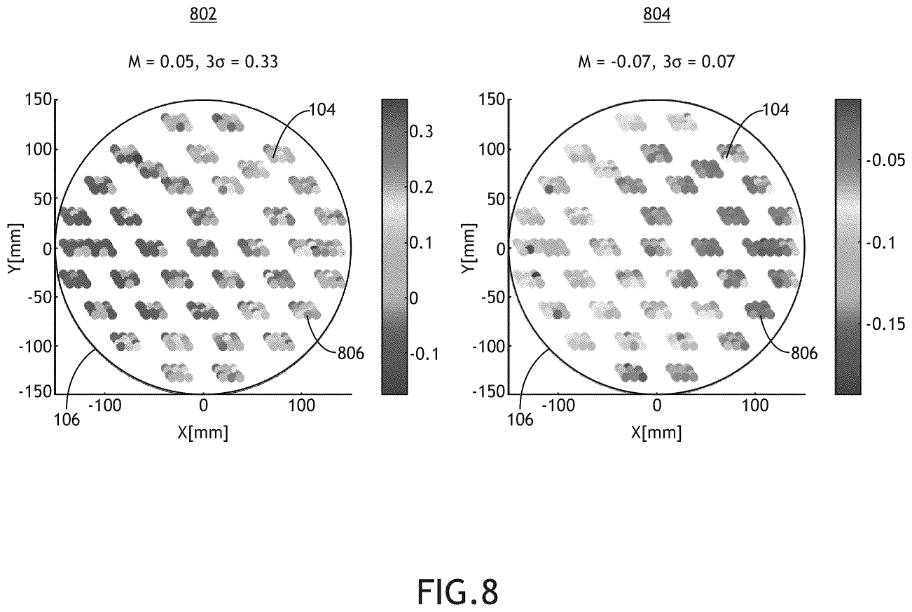

For example, the step 314 may include evaluating a reference design. As an illustration, FIG. 8 includes a conceptual diagram 802 depicting the performance of a relatively low-quality reference design of an optical metrology target 104 and a conceptual diagram 804 depicting the performance of a relatively low-quality reference design of an optical metrology target 104, in accordance with one or more embodiments of the present disclosure. In each diagram 802,804, optical metrology targets 104 distributed across a sample 106 (e.g., within various fields 806) are depicted as circles, where a shading/color of each circle is associated with a deviation of one aspect of the associated optical metrology target 104 with respect to a reference design (e.g., a PPE, or the like). The 3σ variation of the relatively low-quality reference design in diagram 802 is 0.33, whereas the 3σ variation of the relatively high-quality reference design in diagram 804 is 0.07. FIG. 8 further illustrates mean values (M) of the optical metrology measurements.

In a similar manner, the step 314 may include evaluating a metrology recipe (e.g., the first metrology recipe of the optical metrology sub-system 102) used to determine an optical metrology measurement in step 302. As described previously herein, a metrology recipe may include various configurations of the optical metrology sub-system 102 (e.g., wavelength, polarization, field of view, or the like), which may impact the measurement. For example, it may be the case that some metrology recipes may provide more accurate measurements than others. In this way, the step 314 may include adjusting the metrology recipe of the optical metrology sub-system to select a metrology recipe provide a relatively higher accuracy. As another example, it may be the case that different metrology recipes may have different sensitivities to variations of a lithography process associated with fabrication of samples 106. In this way, the step 314 may include adjusting the metrology recipe of the optical metrology sub-system to decrease a sensitivity of the optical metrology measurements to the variations of the lithography process associated with fabrication of the sample 106.

As another example, the step 314 may include selecting a reference design and/or metrology recipe (e.g., from various alternative reference designs). For instance, a reference design and/or metrology recipe may be selected prior to initiating a high-volume manufacturing run. In this application, fabrication tools may fabricate optical metrology targets 104 with a reference design selected in step 314 and/or may utilize a metrology recipe selected in step 314 for process control.

As another example, the step 314 may include switching reference designs (e.g., switching from one reference design to an alternative reference design). For instance, in a high-volume manufacturing run, the steps 302-314 may be used to evaluate a reference design and/or a metrology recipe and determine when the reference design and/or metrology recipe is not meeting a selected metric. As an illustration, an initial reference design and/or metrology recipe for the optical metrology targets 104 may be suitable for process variations during a first phase of the high-volume manufacturing run. However, over time, it may be the case that process variations change such that a different reference design and/or metrology recipe may provide better performance.

As another example, the step 314 may include adjusting the lithography tool to compensate for the variations of the lithography process. For example, the step 314 may reduce or in some cases eliminate such variations in future lithographic exposures.

Referring now to FIGS. 1A-1C, additional aspects of the metrology system 100 are described in greater detail, in accordance with one or more embodiments of the present disclosure.

FIG. 1B is a conceptual diagram of the optical metrology sub-system 102, in accordance with one or more embodiments of the present disclosure.

The optical metrology sub-system 102 may generate one or more images of sample 106 on at least one detector 116 using any method known in the art. In embodiments, the detector 116 is located at a field plane to generate an image of one or more features on the sample 106. In embodiments, the detector 116 is located at a pupil plane to generate an image based on angles of light emanating from the sample 106 (e.g., based on reflection, diffraction, scattering, or the like). In this regard, the optical metrology sub-system 102 may operate as a scatterometry-based metrology tool.

In embodiments, the optical metrology sub-system 102 includes an illumination source 118 to generate an illumination beam 120. The illumination beam 120 may include one or more selected wavelengths of light including, but not limited to, vacuum ultraviolet radiation (VUV), deep ultraviolet radiation (DUV), ultraviolet (UV) radiation, visible radiation, or infrared (IR) radiation. The illumination source 118 may further generate an illumination beam 120 including any range of selected wavelengths. In embodiments, the illumination source 118 may include a spectrally-tunable illumination source to generate an illumination beam 120 having a tunable spectrum.

The illumination source 118 may further produce an illumination beam 120 having any temporal profile. For example, the illumination source 118 may produce a continuous illumination beam 120, a pulsed illumination beam 120, ora modulated illumination beam 120. Additionally, the illumination beam 120 may be delivered from the illumination source 118 via free-space propagation or guided light (e.g. an optical fiber, a light pipe, or the like).

In embodiments, the illumination source 118 directs the illumination beam 120 to a sample 106 via an illumination pathway 122. The illumination pathway 122 may include one or more lenses 124 or additional illumination optical components 126 suitable for modifying and/or conditioning the illumination beam 120. For example, the one or more illumination optical components 126 may include, but are not limited to, one or more polarizers, one or more filters, one or more beam splitters, one or more diffusers, one or more homogenizers, one or more apodizers, one or more beam shapers, or one or more shutters (e.g., mechanical shutters, electro-optic shutters, acousto-optic shutters, or the like). By way of another example, the one or more illumination optical components 126 may include aperture stops to control the angle of illumination on the sample 106 and/or field stops to control the spatial extent of illumination on the sample 106. In one instance, the illumination pathway 122 includes an aperture stop located at a plane conjugate to the back focal plane of the objective lens 128 to provide telecentric illumination of the sample. In embodiments, the optical metrology sub-system 102 includes an objective lens 128 to focus the illumination beam 120 onto the sample 106.

In embodiments, the sample 106 is disposed on a sample stage 130. The sample stage 130 may include any device suitable for positioning the sample 106 within the metrology system 100. For example, the sample stage 130 may include any combination of linear translation stages, rotational stages, tip/tilt stages or the like.

In embodiments, a detector 116 is configured to capture radiation emanating from the sample 106 (e.g., sample light 132) through a collection pathway 134. For example, the collection pathway 134 may include, but is not required to include, a collection lens (e.g. the objective lens 128 as illustrated in FIG. 1) or one or more additional collection pathway lenses 136. In this regard, a detector 116 may receive radiation reflected or scattered (e.g. via specular reflection, diffuse reflection, and the like) from the sample 106 or generated by the sample 106 (e.g. luminescence associated with absorption of the illumination beam 120, or the like).

The collection pathway 134 may further include any number of collection optical components 138 to direct and/or modify illumination collected by the objective lens 128 including, but not limited to one or more collection pathway lenses 136, one or more filters, one or more polarizers, or one or more beam blocks. Additionally, the collection pathway 134 may include field stops to control the spatial extent of the sample imaged onto the detector 116 or aperture stops to control the angular extent of illumination from the sample used to generate an image on the detector 116. In embodiments, the collection pathway 134 includes an aperture stop located in a plane conjugate to the back focal plane of an optical element the objective lens 128 to provide telecentric imaging of the sample.

The detector 116 may include any type of optical detector known in the art suitable for measuring illumination received from the sample 106. For example, a detector 116 may include a sensor suitable for generating one or more images of a static sample 106 (e.g., in a static mode of operation) such as, but is not limited to, a charge-coupled device (CCD), a complementary metal-oxide-semiconductor (CMOS) sensor, a photomultiplier tube (PMT) array, or an avalanche photodiode (APD) array.

By way of another example, a detector 116 may include a sensor suitable for generating one or more images of a sample 106 in motion (e.g., a scanning mode of operation). For instance, the detector 116 may include a line sensor including a row of pixels. In this regard, the optical metrology sub-system 102 may generate a continuous image (e.g., a strip image) one row at a time by translating the sample 106 in a scan direction perpendicular to the pixel row through a measurement field of view and continuously clocking the line sensor during a continuous exposure window.

In another instance, the detector 116 may include a TDI sensor including multiple pixel rows and a readout row. The TDI sensor may operate in a similar manner as the line sensor, except that clocking signals may successively move charge from one pixel row to the next until the charge reaches the readout row, where a row of the image is generated. By synchronizing the charge transfer (e.g., based on the clocking signals) to the motion of the sample along the scan direction, charge may continue to build up across the pixel rows to provide a relatively higher signal to noise ratio compared to the line sensor.

In embodiments, a detector 116 may include a spectroscopic detector suitable for identifying wavelengths of radiation emanating from the sample 106. In embodiments, the optical metrology sub-system 102 may include multiple detectors 116 (e.g. associated with multiple beam paths generated by one or more beamsplitters to facilitate multiple metrology measurements by the optical metrology sub-system 102. For example, the optical metrology sub-system 102 may include one or more detectors 116 suitable for static mode imaging and one or more detectors 116 suitable for scanning mode imaging. In embodiments, the optical metrology sub-system 102 may include one or more detectors 116 suitable for both static and scanning imaging modes.

In embodiments, as illustrated in FIG. 1B, the optical metrology sub-system 102 includes a beamsplitter 140 oriented such that the objective lens 128 may simultaneously direct the illumination beam 120 to the sample 106 and collect radiation emanating from the sample 106. In this regard, the metrology system 100 may be configured in an epi-illumination mode.

In embodiments, the angle of incidence of the illumination beam 120 on the sample 106 is adjustable. For example, the path of the illumination beam 120 through the beamsplitter 140 and the objective lens 128 may be adjusted to control the angle of incidence of the illumination beam 120 on the sample 106. In this regard, the illumination beam 120 may have a nominal path through the beamsplitter 140 and the objective lens 128 such that the illumination beam 120 has a normal incidence angle on the sample 106. By way of another example, the angle of incidence of the illumination beam 120 on the sample 106 may be controlled by modifying the position and/or angle of the illumination beam 120 on the beamsplitter 140 (e.g. by rotatable mirrors, a spatial light modulator, a free-form illumination source, or the like). In embodiments, the illumination source 118 directs the one or more illumination beam 120 to the sample 106 at an angle (e.g. a glancing angle, a 45-degree angle, or the like).

FIG. 1C is a conceptual diagram of the additional metrology sub-system 108, in accordance with one or more embodiments of the present disclosure.

In embodiments, the additional metrology sub-system 108 includes an illumination source 118. In embodiments, the illumination source 118 includes a particle source (e.g., an electron beam source, an ion beam source, or the like) such that the illumination beam 120 includes a particle beam (e.g., an electron beam, a particle beam, or the like). The illumination source 118 may include any particle source known in the art suitable for generating an illumination beam 120. For example, the illumination source 118 may include, but is not limited to, an electron gun or an ion gun. In embodiments, the illumination source 118 is configured to provide a particle beam with a tunable energy. For example, an illumination source 118 including an electron source may, but is not limited to, provide an accelerating voltage in the range of 0.1 kV to 30 kV. As another example, an illumination source 118 including an ion source may, but is not required to, provide an ion beam with an energy in the range of 1 to 50 keV.

In embodiments, the illumination pathway 122 includes one or more particle focusing elements (e.g., lenses 124, or the like) and/or corrective elements (e.g., stigmators, or the like). For example, the one or more particle focusing elements may include, but are not limited to, a single particle focusing element or one or more particle focusing elements forming a compound system. In embodiments, the one or more particle focusing elements include objective lens 128 configured to direct the illumination beam 120 to the sample 106. Further, the one or more particle focusing elements may include any type of electron lenses known in the art including, but not limited to, electrostatic, magnetic, uni-potential, or double-potential lenses. It is noted herein that the description of a voltage contrast imaging inspection system as depicted in FIG. 1C and the associated descriptions above are provided solely for illustrative purposes and should not be interpreted as limiting. For example, the additional metrology sub-system 108 may include any excitation source known in the art suitable for generating inspection data on a sample 106. In embodiments, the additional metrology sub-system 108 includes two or more particle beam sources (e.g., electron beam sources or ion beam sources) for the generation of two or more particle beams. In a further embodiment, the additional metrology sub-system 108 may include one or more components (e.g., one or more electrodes) configured to apply one or more voltages to one or more locations of the sample 106. In this regard, the additional metrology sub-system 108 may generate voltage contrast imaging data.

In embodiments, the additional metrology sub-system 108 includes one or more particle detectors 116 to image or otherwise detect particles emanating from the sample 106. In embodiments, the detector 116 includes an electron collector (e.g., a secondary electron collector, a backscattered electron detector, or the like). In embodiments, the detector 116 includes a photon detector (e.g., a photodetector, an x-ray detector, a scintillating element coupled to photomultiplier tube (PMT) detector, or the like) for detecting electrons and/or photons from the sample surface.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A metrology system comprising:
a controller communicatively coupled to an optical metrology sub-system and an additional metrology sub-system, wherein the optical metrology sub-system is configurable in accordance with a first metrology recipe to generate optical metrology measurements of one or more optical metrology targets on one or more samples, wherein the optical metrology measurements are based on features of the optical metrology targets associated with at least one optical pitch, wherein the additional metrology sub-system is configurable in accordance with a second metrology recipe to generate additional metrology measurements of the one or more optical metrology targets, wherein the additional metrology measurements have a higher resolution than the optical metrology measurements, wherein the additional metrology sub-system further measures deviations of the one or more optical metrology targets from a reference design, wherein the deviations include deviations of the features associated with the at least one optical pitch relative to the reference design, wherein the controller includes one or more processors configured to execute program instructions causing the one or more processors to:
compare the optical metrology measurements with the additional metrology measurements to generate accuracy measurements for the one or more optical metrology targets;
identify variations of a lithography process for fabricating the one or more samples based on the deviations of the of the one or more optical metrology targets from the reference design;
correlate the accuracy measurements of the one or more optical metrology targets to the variations of the lithography process based on the deviations of the of the one or more optical metrology targets from the reference design; and
adjust at least one of the optical metrology sub-system, a lithography tool, or the reference design based on the correlations.

2. The metrology system of claim 1, wherein measuring deviations of the one or more optical metrology targets from reference designs based on the additional measurements comprises:
measuring at least one of sidewall angles, asymmetries, pattern placement errors, or etch bias of the features associated with the at least one optical pitch.

3. The metrology system of claim 1, wherein the one or more optical metrology targets further include features associated with a fine pitch smaller than the at least one optical pitch, wherein measuring deviations of the one or more optical metrology targets from reference designs based on the additional measurements comprises:
measuring at least one of sidewall angles, asymmetries, pattern placement errors, or etch bias of the features associated with the fine pitch.

4. The metrology system of claim 1, wherein measuring deviations of the one or more optical metrology targets from reference designs based on the additional measurements comprises:
measuring layer-specific deviations of the one or more optical metrology targets.

5. The metrology system of claim 1, wherein the one or more optical metrology targets include features distributed with one or more pitches, wherein measuring deviations of the one or more optical metrology targets from reference designs based on the additional measurements comprises:
measuring pitch-specific deviations of the one or more optical metrology targets.

6. The metrology system of claim 1, wherein identifying variations of the lithography process for fabricating the one or more samples based on the deviations of the of the one or more optical metrology targets from the reference design comprises:
identifying variations of the lithography process between different spatial locations across a particular one of the one or more samples.

7. The metrology system of claim 1, wherein the one or more samples includes two or more samples, wherein identifying variations of the lithography process for fabricating the one or more samples based on the deviations of the of the one or more optical metrology targets from the reference design comprises:
identifying variations of the lithography process across time for at least two of the two or more samples.

8. The metrology system of claim 1, wherein adjusting at least one of the optical metrology sub-system, the lithography tool, or the reference design based on the correlations comprises:
adjusting the first metrology recipe to decrease a sensitivity of the optical metrology measurements to the variations of the lithography process.

9. The metrology system of claim 8, wherein adjusting the first metrology recipe to decrease a sensitivity of the optical metrology measurements to the excursions comprises:
adjusting at least one of an illumination wavelength, an illumination polarization, an illumination angle, or a field of view of the optical metrology sub-system.

10. The metrology system of claim 1, wherein adjusting at least one of the optical metrology sub-system, the lithography tool, or the reference design based on the correlations comprises:
adjusting the lithography tool to compensate for the variations of the lithography process.

11. The metrology system of claim 1, wherein adjusting at least one of the optical metrology sub-system, the lithography tool, or the reference design based on the correlations comprises:
switching the reference design to an alternative reference design; and
directing the lithography tool to fabricate one or more additional optical metrology targets on one or more additional samples based on the alternative reference design.

12. The metrology system of claim 1, wherein the optical metrology sub-system generates the optical metrology measurements based on one or more images of the one or more optical metrology targets.

13. The metrology system of claim 1, wherein the optical metrology sub-system generates the optical metrology measurements based on one or more scatterometry measurements of the one or more optical metrology targets.

14. The metrology system of claim 1, wherein the at least one optical pitch includes a single optical pitch, wherein the one or more optical metrology targets include features with the single optical pitch on at least two layers.

15. The metrology system of claim 1, wherein the at least one optical pitch includes a first optical pitch and a second optical pitch.

16. The metrology system of claim 15, wherein the first and second optical pitches are resolvable with the optical metrology sub-system.

17. The metrology system of claim 1, wherein the one or more optical targets include features with a first pitch and a second pitch, wherein at least one of the first or the second pitches are not resolvable with the optical metrology sub-system, wherein the optical pitch comprises a Moiré pitch based on the first and second pitches and is resolvable by the optical metrology sub-system.

18. The metrology system of claim 1, wherein the additional metrology sub-system comprises:
at least one of a particle-beam metrology system or an X-ray metrology system.

19. A method comprising:
generating optical metrology measurements of one or more optical metrology targets on one or more samples with an optical metrology sub-system in accordance with a first metrology recipe, wherein the one or more optical metrology targets include features associated with at least one optical pitch, wherein the optical metrology measurements are based on the features of the optical metrology targets with the at least one optical pitch;
generating additional metrology measurements of the one or more optical metrology targets with an additional metrology sub-system configurable in accordance with a second metrology recipe, wherein the additional metrology measurements have a higher resolution than the optical metrology measurements;
comparing the optical metrology measurements with the additional metrology measurements to generate accuracy measurements for the one or more optical metrology targets;
measuring deviations of the one or more optical metrology targets from a reference design with the additional metrology sub-system, wherein the deviations include deviations of the optically-resolvable features from the reference design;
identifying variations of a lithography process for fabricating the one or more samples based on the deviations of the of the one or more optical metrology targets from the reference design;
correlating the accuracy measurements of the one or more optical metrology targets to the variations of the lithography process based on the deviations of the of the one or more optical metrology targets from the reference design; and
adjusting at least one of the optical metrology sub-system, a lithography tool, or the reference design based on the correlations.

20. A metrology system comprising:
an optical metrology sub-system configurable in accordance with a first metrology recipe to generate optical metrology measurements of one or more optical metrology targets on one or more samples, wherein the optical metrology measurements are based on features of the optical metrology targets associated with at least one optical pitch;
an additional metrology sub-system configurable in accordance with a second metrology recipe to generate additional metrology measurements of the one or more optical metrology targets, wherein the additional metrology measurements have a higher resolution than the optical metrology measurements, wherein the additional metrology sub-system further measures deviations of the one or more optical metrology targets from a reference design, wherein the deviations include deviations of the features associated with the at least one optical pitch relative to the reference design; and
a controller communicatively coupled to the optical metrology sub-system and the additional metrology sub-system, the controller including one or more processors configured to execute program instructions causing the one or more processors to:
compare the optical metrology measurements with the additional metrology measurements to generate accuracy measurements for the one or more optical metrology targets;
identify variations of a lithography process for fabricating the one or more samples based on the deviations of the of the one or more optical metrology targets from the reference design;
correlate the accuracy measurements of the one or more optical metrology targets to the variations of the lithography process based on the deviations of the of the one or more optical metrology targets from the reference design; and
adjust at least one of the optical metrology sub-system, a lithography tool, or the reference design based on the correlations.

21. The metrology system of claim 20, wherein the optical metrology sub-system generates the optical metrology measurements based on one or more images of the one or more optical metrology targets.

22. The metrology system of claim 20, wherein the optical metrology sub-system generates the optical metrology measurements based on one or more scatterometry measurements of the one or more optical metrology targets.

23. The metrology system of claim 20, wherein the at least one optical pitch includes a single optical pitch, wherein the one or more optical metrology targets include features with the single optical pitch on at least two layers.

24. The metrology system of claim 20, wherein the at least one optical pitch includes a first optical pitch and a second optical pitch.

25. The metrology system of claim 24, wherein the first and second optical pitches are resolvable with the optical metrology sub-system.

26. The metrology system of claim 20, wherein the one or more optical targets include features with a first pitch and a second pitch, wherein at least one of the first or the second pitches are not resolvable with the optical metrology sub-system, wherein the optical pitch comprises a Moiré pitch based on the first and second pitches and is resolvable by the optical metrology sub-system.

27. The metrology system of claim 20, wherein the additional metrology sub-system comprises:
at least one of a particle-beam metrology system or an X-ray metrology system.
